(19) United States
(12) Patent Application Publication
(10) Pub. No.: US 2024/0413133 A1
(43) Pub. Date: Dec. 12, 2024

(54) WAFER WITH MICRO INTEGRATED CIRCUITS

(71) Applicant: Lextar Electronics Corporation, Hsinchu City (TW)

(72) Inventors: Shiou-Yi KUO, Hsinchu City (TW); Chin-Hung LUNG, Hsinchu City (TW); Bo-Yu CHEN, Hsinchu City (TW)

(21) Appl. No.: 18/733,292

(22) Filed: Jun. 4, 2024

(30) Foreign Application Priority Data
Jun. 6, 2023 (TW) 112120985

(51) Int. Cl. H01L 25/075

(52) U.S. Cl. CPC H01L 25/0753

(57) ABSTRACT

A wafer with micro integrated circuits includes a transparent substrate and a plurality of micro components. The micro components are each attached to the transparent substrate by a plurality of transparent adhesive layers. Each of the micro components includes a bonding pad in direct contact with the transparent adhesive layer and an etching stop layer located on the side of the micro components opposite from the bonding pad.

### CROSS REFERENCE TO RELATED APPLICATIONS

This application claims priority of Taiwan Patent Application No. 112120985 filed on Jun. 6, 2023, and the content of the entirety of which is incorporated by reference herein.

### BACKGROUND OF THE DISCLOSURE

### Field of the Disclosure

The present disclosure relates to a wafer, and in particular to a wafer with micro integrated circuits.

### Description of the Related Art

As technology advances, various types of electronic products are developed to be lighter, thinner, shorter, and smaller, and the technology of fine pitch packaging, which is related to the packaging of electronic products, is also gradually advancing, in order to bring more competitive electronic products to market. In general, the semiconductor components are usually packaged before being used to drive the circuit or component. Alternatively, the semiconductor device and the circuit or component may be packaged in the same package to form a semiconductor device with its own driver component, though the requirement of process technology (e.g., mass transfer process) and cost may be higher. Therefore, although the existing technology has been generally adequate for its intended purposes, it has not been entirely satisfactory in every aspect.

### BRIEF SUMMARY OF THE DISCLOSURE

An embodiment of the present disclosure provides a wafer with micro integrated circuits, including a transparent substrate and a plurality of micro components. The micro components are attached to the transparent substrate by a plurality of transparent adhesive layers. Each of the micro components includes a bonding pad in direct contact with the transparent adhesive layer and an etching stop layer located on the side of the micro component opposite from the bonding pad.

An embodiment of the present disclosure provides a semiconductor device with micro integrated circuit, including four external electrodes corresponding to a voltage source, a ground line, a select line, and a data line. The semiconductor device further includes three light-emitting diodes. The semiconductor device further includes a micro component, which has a trapezoidal shape in a cross-sectional view. The semiconductor device further includes a dielectric layer encapsulating a side surface of the micro component. The semiconductor device has seven electrodes. Four of said seven electrodes are input terminals and are electrically connected to the four external electrodes corresponding to the voltage source, the ground line, the select line, and the data line. The other three electrodes are output terminals and are electrically connected to the three respective light-emitting diodes.

### BRIEF DESCRIPTION OF THE DRAWINGS

Aspects of the present disclosure can be fully understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a cross-sectional view at intermediate stages of manufacturing the wafer with micro integrated circuits according to some embodiment of the present disclosure;

FIG. 2 illustrates a cross-sectional view of performing an etching process on the semiconductor wafer according to some embodiment of the present disclosure;

FIG. 3 illustrates a cross-sectional view of forming a transparent adhesive layer on the semiconductor wafer according to some embodiment of the present disclosure;

FIG. 4 illustrates a cross-sectional view of securing a transparent substrate to the semiconductor wafer by the transparent adhesive layer according to some embodiment of the present disclosure;

FIG. 5 illustrates a cross-sectional view of the wafer after performing a thinning process according to some embodiment of the present disclosure;

FIG. 6 illustrates a cross-sectional view of the wafer after partially removing the transparent adhesive layer between the micro components according to some embodiment of the present disclosure;

FIG. 7 illustrates a cross-sectional view at intermediate stages of the wafer performing a laser mass transfer process according to some embodiment of the present disclosure;

FIG. 8 illustrates a cross-sectional view of the micro components of the wafer being transferred to a carrier according to some embodiment of the present disclosure;

FIG. 9 illustrates a partial top view of the semiconductor device with micro integrated circuit according to some embodiment of the present disclosure;

FIG. 10 illustrates a cross-sectional view of the semiconductor device according to some embodiment of the present disclosure; and

FIG. 11 illustrates a circuit diagram of the semiconductor device with three sets of micro components of the 2TIC structure according to some embodiment of the present disclosure.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during the manufacturing process, as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Some embodiments of the disclosure are described. Additional operations can be provided before, during, and/or after the stages described in these embodiments. Some of the stages that are described can be replaced or eliminated for different embodiments. Additional features can be added to the embodiments. Some of the features described below can be replaced or eliminated for different embodiments. Although some embodiments are discussed with operations performed in a particular order, these operations may be performed in another logical order.

The embodiments of the present disclosure provide a technology that combines a semiconductor etching process and a laser mass transfer process to form a wafer with micro integrated circuits. For example, after the semiconductor components are manufactured, instead of singulating the wafer (i.e., cutting it into individual chips), the wafer with micro integrated circuits are obtained by separating the semiconductor components on the substrate through a separating process, for example, etching process or cutting process, and then transferring the separated semiconductor components to a carrier through a transfer process. The foregoing wafer may continue to be used in the transfer process of semiconductor components, thereby simplifying the process and reducing the production costs. In addition, the methods provided in the present disclosure may be further applied to other active components or passive components to achieve the effect of module shrinkage.

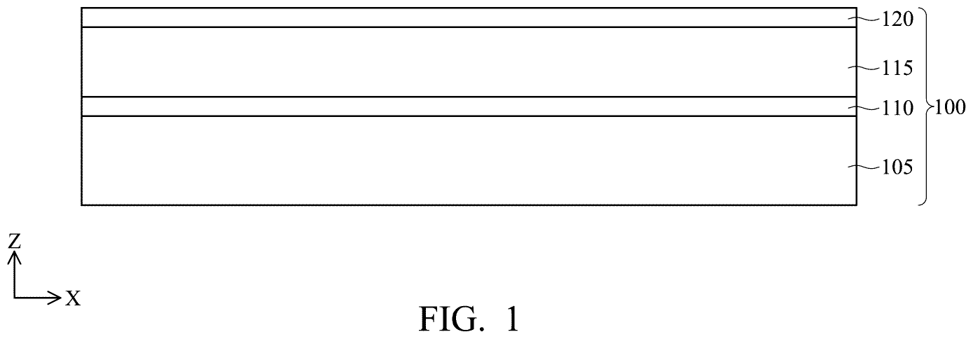

FIG. 1 illustrates a cross-sectional view of manufacturing the wafer 10 with micro integrated circuits at intermediate stages according to some embodiment of the present disclosure. In some embodiments, a semiconductor wafer 100 is provided. In some embodiments, the semiconductor wafer 100 includes a native substrate 105, an etching stop layer 110, a circuit layer 115, and a bonding pad layer 120 from bottom to top in direction Z. In some embodiments, the native substrate 105 may be an elemental semiconductor substrate, such as a silicon substrate, or a germanium substrate; a compound semiconductor substrate, such as a silicon carbide (SiC), gallium arsenide (GaAs), indium arsenide (InAs), indium phosphide (InP), silicon germanium (SiGe), gallium arsenic phosphide (GaAsP), or gallium indium phosphide (GaInP) substrate. In other embodiments, the native substrate 105 may be a silicon-on-insulator (SOI) substrate.

Continuing to refer to FIG. 1, in some embodiments, the etching stop layer 110 may serve as a mask in subsequent etching process. In some embodiments, the circuit layer 115 may subsequently drive other circuits or devices, while the bonding pad layer 120 may electrically connect the components in the circuit layer 115 to the external circuits. In some embodiments, the circuit layer 115 is between the etching stop layer 110 and the bonding pad layer 120. In some embodiments, the circuit layer 115 may include an active circuit element or a passive circuit element. In some embodiments, the active circuit element may be a p-type field effect transistor (PFET), a n-type FET (NFET), a metal-oxide-semiconductor field effect transistor (MOSFET), a complementary metal-oxide-semiconductor (CMOS) transistor, a bipolar transistor, a high voltage transistor, or a high frequency transistor. In some embodiments, the passive circuit element may be a resistor, a capacitor, or an inductor. In some embodiments, the material of the circuit layer 115 may include silicon, gallium arsenide, or a combination thereof. In some embodiments, the material of the etching stop layer 110 may include silicon nitride, silicon carbide, or a combination thereof. In some embodiments, the material of the bonding pad layer 120 may include Al, Cu, Au, TiN, Ti, Pt, Cr, Ni, Pd, or a combination thereof.

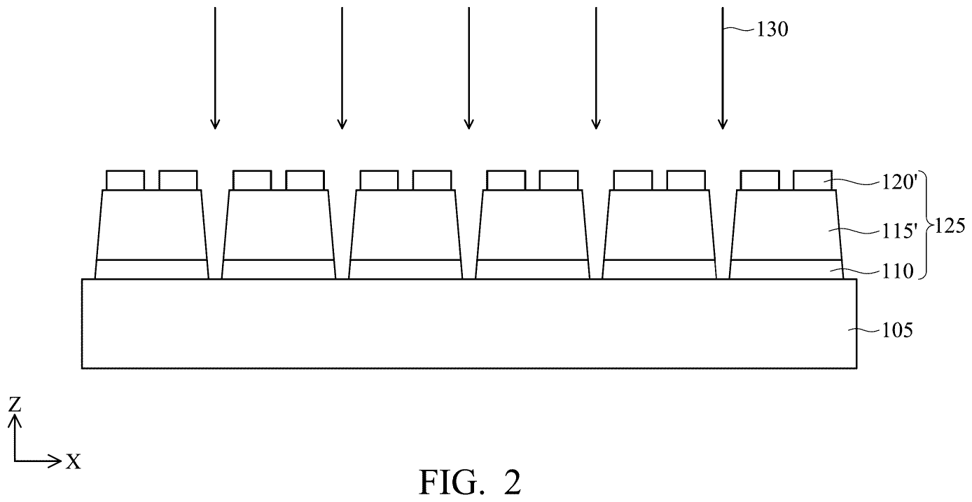

FIG. 2 illustrates a cross-sectional view of performing an etching process 130 on the semiconductor wafer 100 according to some embodiment of the present disclosure. Referring to FIG. 2, the etching process 130 is performed on the semiconductor wafer 100 until the etching stop layer 110, the circuit layer 115, and the bonding pad layer 120 on the native substrate 105 are separated into a plurality of micro components 125. In the embodiment of the present disclosure, instead of forming the plurality of micro components 125 along with separating the native substrate 105, the native substrate 105 is not etched during the etching process 130 and supports all the micro components 125 thereon to proceed with a subsequent transfer process.

Continuing to refer to FIG. 2, in some embodiments, each of the micro components 125 includes a bonding pad 120′, an etching stop layer 110, and a circuit layer 115′ between the etching stop layer 110 and the bonding pad 120′ after performing the etching process 130. In some embodiments, the circuit layer 115′ is formed as a tapered structure with a long side, a short side opposite to the long side, and inclined sidewalls between the long side and the short side, rather than having straight sidewalls because the semiconductor wafer 100 is not being cut but being etched by the etching process 130. The short side of the tapered structure corresponds to the side of the circuit layer 115′ near the bond pad 120′, and the long side of the tapered structure corresponds to the side of the circuit layer 115′ near the etching stop layer 110. In some embodiments, the etching process 130 may include an anisotropic etching process (or directional etching process), such as reactive ion etching (RIE) process, plasma etching, inductively coupled plasma (ICP) etching, or dry etching processes of a combination thereof. In some embodiments, the angle between the long side of the tapered structure (the side of the circuit layer 115′ near the etching stop layer 110) and the sidewall of the tapered structure is from 45 degrees to 90 degrees. In some embodiments, the thickness of the micro components 125 is less than 30 μm. In some embodiments, the distance between adjacent two of the micro components 125 is from about 0.5 μm to about 100 μm. In some embodiments, the etching process 130 is performed by applying a photoresist mask layer (not shown) to the semiconductor wafer 100 by a process such as photolithography first, and then performing inductively coupled plasma (ICP) etching using carbon tetrafluoride/oxygen/chlorine/boron trichloride as an etchant.

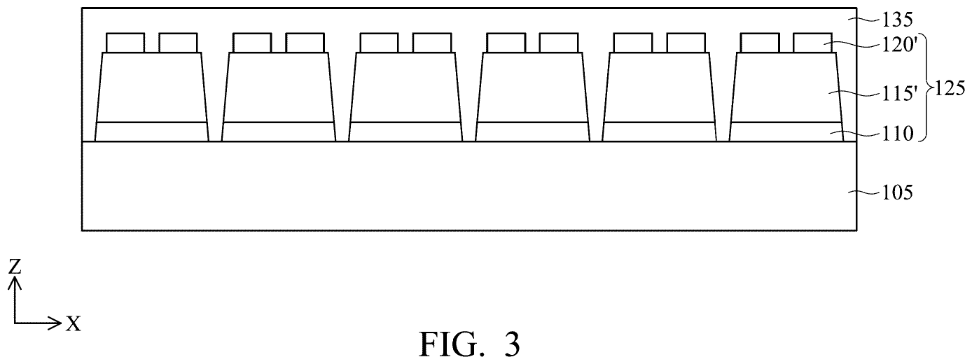

FIG. 3 illustrates a cross-sectional view of forming a transparent adhesive layer 135 on the micro components 125 and the native substrate 105 according to some embodiment of the present disclosure. Specifically, the transparent adhesive layer 135 covers the micro components 125 and the native substrate 105 so that the micro components 125 are embedded in the transparent adhesive layer 135. In some embodiments, the transparent adhesive layer 135 includes a laser dissociative material suitable for the subsequent transfer process. In some embodiments, the material of the transparent adhesive layer 135 includes a polyimide, an epoxy resin, a silicone resin, a polydimethylsiloxane (PDMS), or a polymethyl methacrylate (PMMA). In some embodiments, the thickness of the transparent adhesive layer 135 is from about 0.5 μm to about 50 μm.

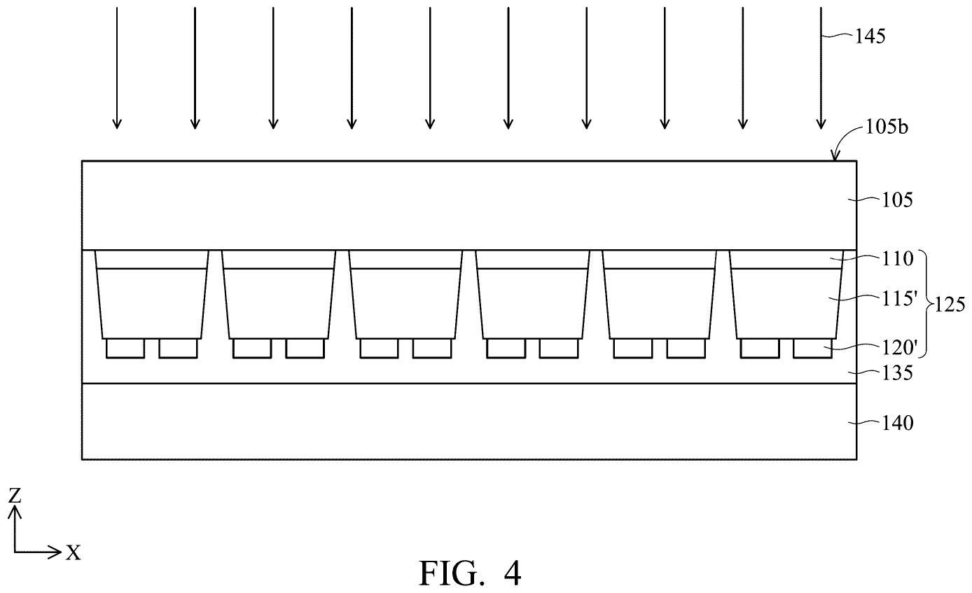

FIG. 4 illustrates a cross-sectional view of securing a transparent substrate 140 to the transparent adhesive layer 135 according to some embodiment of the present disclosure. Specifically, the native substrate 150 and the micro components 125 thereon are attached to the transparent substrate 140 via the transparent adhesive layer 135. In some embodiment, the transparent substrate 140 is turned up-side-down after securing to the transparent adhesive layer 135, therefore the bottom surface 105b of the native substrate 105 is facing upward. In some embodiments, the transparent substrate 140 can be penetrated by the laser in the subsequent transfer process. In some embodiments, the material of the transparent substrate 140 may include glass, aluminum oxide, or sapphire substrate. In some embodiments, the thickness of the transparent substrate 140 is from about 50 μm to about 2 mm.

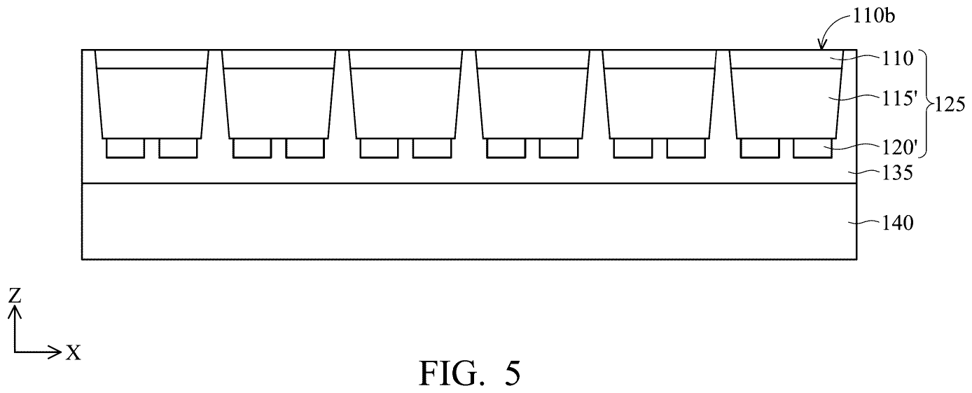

Referring to FIG. 4 and FIG. 5, the thinning process 145 is performed on the bottom surface 105b of the native substrate 105 to remove the native substrate 105. FIG. 5 illustrates a cross-sectional view of the wafer 10 after performing the thinning process 145 according to some embodiment of the present disclosure. As shown in FIG. 5, after performing the thinning process 145, the native substrate 105 is completely removed and the bottom surfaces 110b of the etching stop layers 110 of the micro components 125 is exposed. The micro components 125 remain secured to the transparent substrate 140 by the transparent adhesive layer 135. In some embodiments, the thinning process 145 may include more than two thinning steps, including thinning the native substrate 105 to about 100 μm left, and then etching the remaining native substrate 105 with other etching processes to avoid damaging the micro components 125 and to reduce the difficulty of the process. In some embodiments, the thinning process 145 may include chemical mechanical polishing (CMP) treatment, dry etching, wet etching, or a combination thereof.

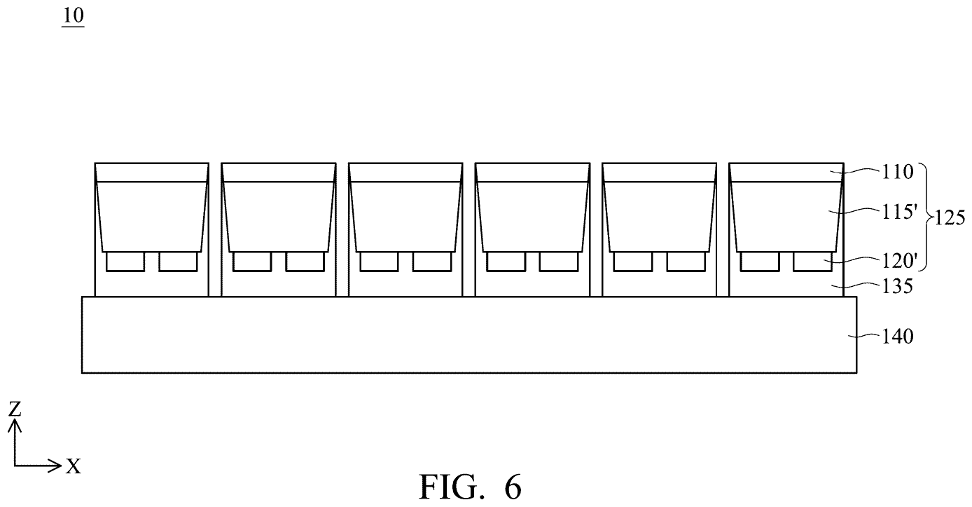

FIG. 6 illustrates a cross-sectional view after removing the transparent adhesive layer 135 partially between the micro components 125 according to some embodiment of the present disclosure. After exposing the bottom surfaces 110b of the etching stop layers 110 of the micro components 125, an anisotropic etching process may continue to be performed to remove the transparent adhesive layer 135 between the micro components 125, such as performing reactive ion etching (RIE) process, plasma etching, inductively coupled plasma (ICP) etching, or dry etching of a combination thereof. More specifically, by using the etching stop layers 110 as masks, the etching process partially (vertically) etches the transparent adhesive layer 135 such that the transparent adhesive layer 135 is divided into several portions and each of the portions exists only between the corresponding one of the micro components 125 and the transparent substrate 140. After partially removing the transparent adhesive layer 135 between the micro components 125, the wafer 10 with micro integrated circuits (micro components 125) may be formed. In other words, the wafer 10 includes the transparent substrate 140 and the micro components 125, and the micro components 125 are secured to the transparent substrate 140 by the transparent adhesive layer 135. Each of the micro components 125 includes a bonding pad 120′ that is in direct contact with the transparent adhesive layer 135, an etching stop layer 110 that is located on the opposite side of the micro components 125 from the bonding pad 120′, and a circuit layer 115′ that is between the etching stop layer 110 and the bonding pad 120′. In some embodiments, the wafer 10 may continue with further operations, such as transferring the micro components 125 to another carrier via the transfer process.

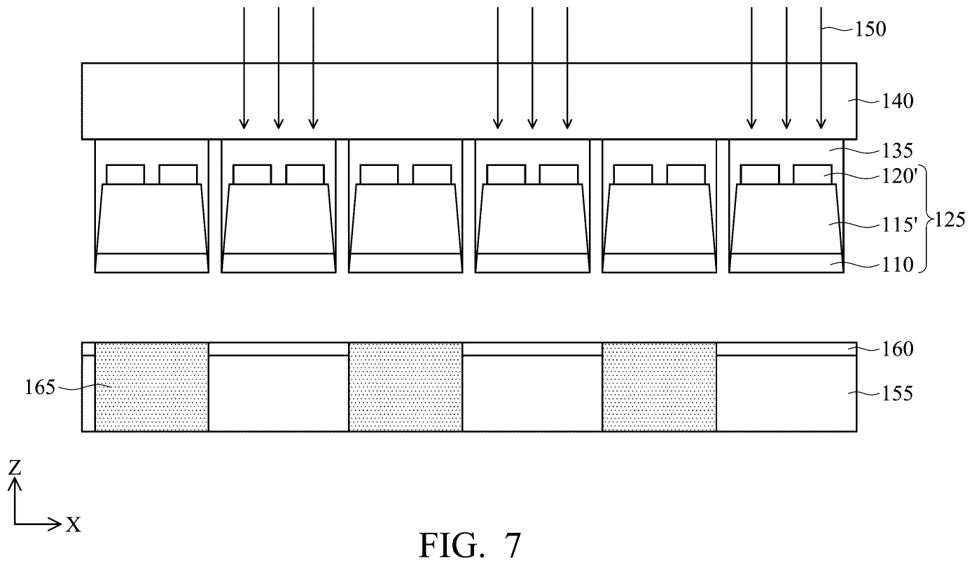

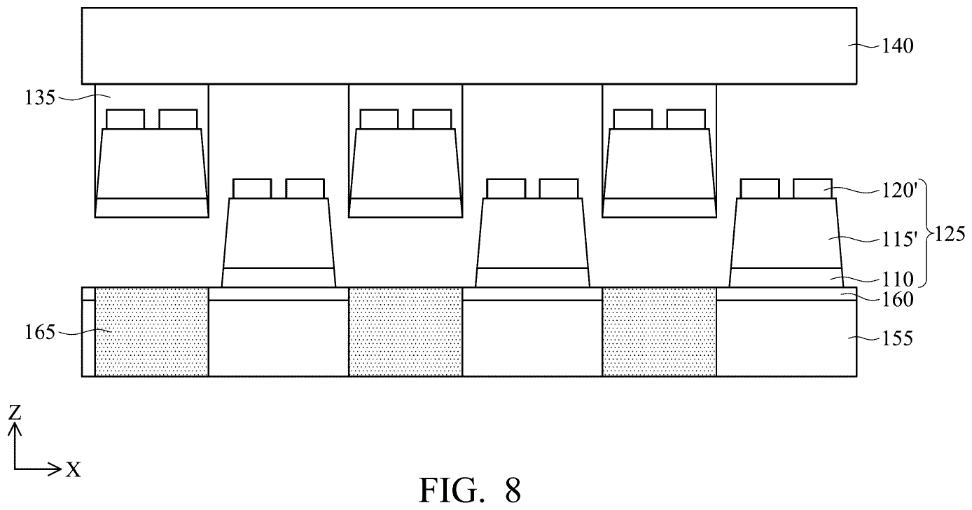

Referring then to FIGS. 7 and 8, FIG. 7 illustrates a cross-sectional view of the wafer 10 performing a laser mass transfer process 150 at intermediate stages according to some embodiment of the present disclosure. FIG. 8 illustrates a cross-sectional view of the micro components 125 of the wafer 10 being transferred to a carrier 155 according to some embodiment of the present disclosure. The laser mass transfer process 150 is then performed with the transparent substrate 140 facing upward and the micro components 125 facing downward. First, the carrier 155 is provided with an adhesive layer 160 and a solder pad 165, where the adhesive layer 160 may be used to secure the micro components 125 in the wafer 10 transferred by the laser mass transfer process 150 to the carrier 155, and the solder pad 165 may be subsequently bonded to other circuits. Next, the laser mass transfer process 150 is performed on the wafer 10. More specifically, referring to FIG. 7, the laser mass transfer process 150 utilizes a laser beam to penetrate the transparent substrate 140 and irradiate the predetermined micro components 125, such that the transparent adhesive layer 135 between the predetermined micro components 125 and the transparent substrate 140 for securing the micro components 125 and the transparent substrate 140 is dissociated (i.e., dissociatively damaged) by the laser beam, thereby the predetermined micro components 125 are separated from the transparent substrate 140 and fall off (drop). In this way, a mass transfer process similar to that of a light-emitting diode may be accomplished in such a manner as to simultaneously transfer a large number of micro components 125 to the carrier 155. In some embodiments, the laser mass transfer process 150 may use a light source that does not overheat the micro components 125 during the irradiation process, such as a quasi-molecular laser light source, or a semiconductor-pumped solid-state laser light source. In some embodiment, the laser mass transfer process 150 may transfer only one or all of the micro components 125 of the wafer 10, the transferring quantity may be varied according to the need.

Continuing with FIG. 8, in some embodiments, the micro components 125 that are irradiated by the laser beam and separated from the transparent substrate 140 fall onto the carrier 155 and are secured to the carrier 155 by the adhesive layer 160 on the carrier 155. The micro components 125 that are not irradiated during the laser mass transfer process 150 are still secured to the transparent substrate 140 after the laser mass transfer process 150 is performed because the transparent adhesive layer 135 between the micro components 125 and the transparent substrate 140 has not been dissociated by the laser. In some embodiments, the micro components 125 are transferred to the carrier 155 as control components of the carrier 155. In some embodiments, the material of the adhesive layer 160 may include benzocyclobutene (BCB), polyimide (PI), polybenzoxazole (PBO), epoxy resin, and/or silicone resin. In some embodiments, the carrier 155 may include a thin film transistor (TFT) substrate, a glass substrate, a ceramic substrate, a semiconductor substrate, a complementary metal-oxide-semiconductor (CMOS) circuit substrate, a liquid crystal on silicon (LCOS) substrates, a printed circuit board (PCB), a silicon (Si) substrate, an aluminum oxide (Al₂O₃) substrate, etc.

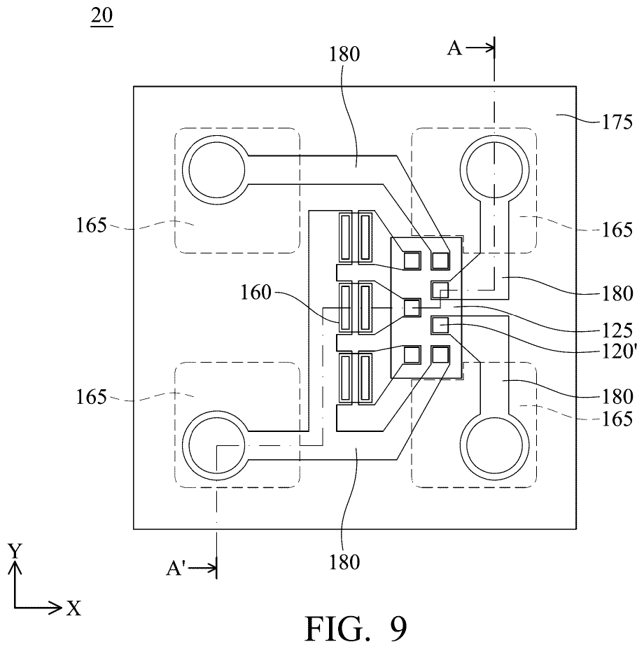

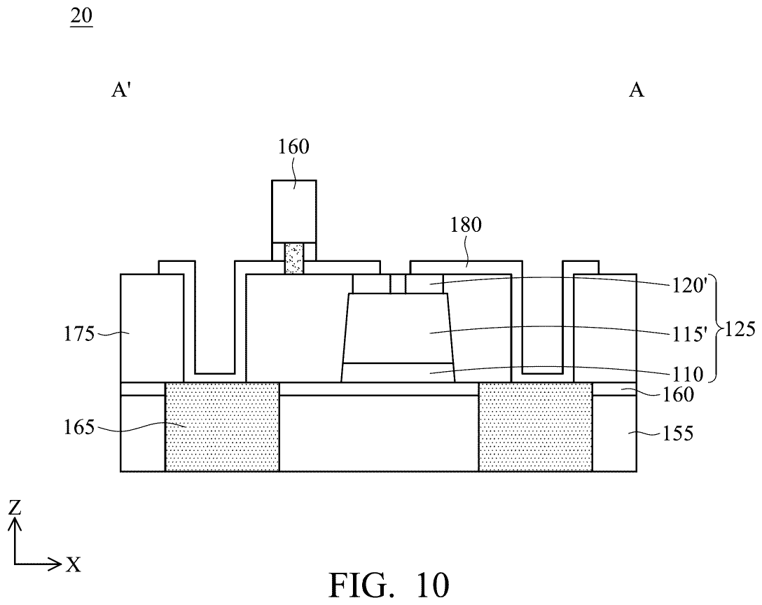

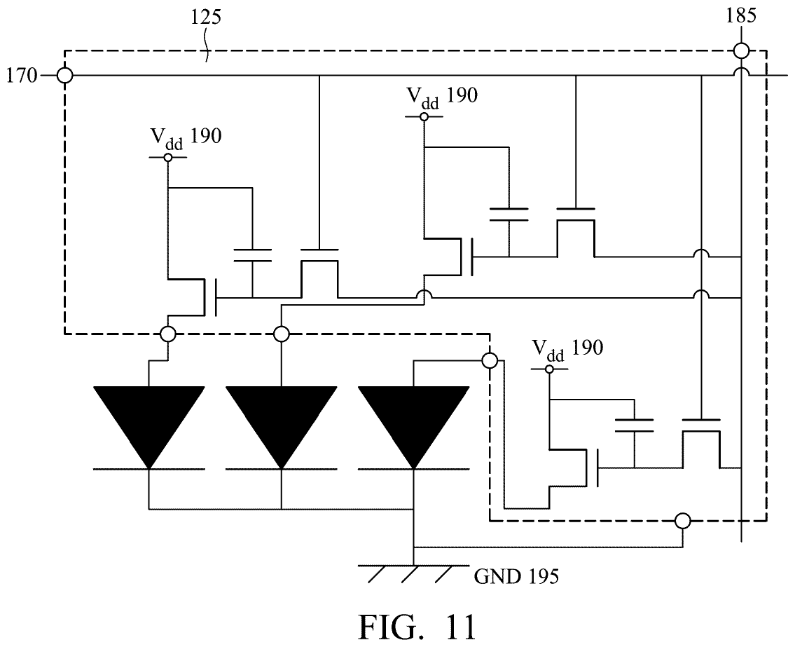

Referring to FIG. 9 with FIGS. 10 and 11 next, FIG. 9 illustrates a partial top view of the semiconductor device 20 with a micro integrated circuit according to some embodiment of the present disclosure. FIG. 10 illustrates a cross-sectional view of the semiconductor device 20 along the cross-section A-A′ of FIG. 9 according to some embodiment of the present disclosure. FIG. 11 illustrates a circuit diagram of the semiconductor device 20 with three sets of micro components 125 of the 2TIC structure according to some embodiment of the present disclosure. In some embodiments, the semiconductor device 20 comprises a carrier 155, a plurality of light-emitting diodes 160 on the carrier 155, and a micro component 125 between the carrier 155 and the light-emitting diodes 160. The micro component 125 may act as a control component of the semiconductor device 20. For example, the micro component 125 may control the light-emitting diodes 160. In some embodiments, the semiconductor device 20 further includes a dielectric layer 175 and a plurality of redistribution layer 180, and the micro components 125 may be connected to other components of the semiconductor device 20 via the redistribution circuit 180. In some embodiments, referring to FIGS. 9 to 11, the semiconductor device 20 includes four electrodes (e.g., solder pads 165). In some embodiments, the four electrodes are corresponding to different external terminals. Specifically, the four electrodes respectively connect to a voltage source (Vdd) 190, a ground line (GND) 195, a select line 185, and a data line 170. The micro component 125 in the semiconductor device 20 is internally designed with three sets of 2TIC (a combination of two transistors and one capacitor) driver circuits to control the light-emitting diodes 160 respectively. In some embodiments, the micro component 125 has at least seven electrodes (e.g. bonding pads 120′). In some embodiments, four of the foregoing seven electrodes are input terminals and are electrically connected to the four electrodes (e.g., solder pads 165) by the corresponding one of the redistribution layers 180 respectively. In some embodiments, the other three of the foregoing seven electrodes are output terminals and are electrically connected to the positive electrodes of the light-emitting diodes 160 by the corresponding one of the redistribution layers 180 respectively. The semiconductor device 20 determines the switching of the light-emitting diodes 160 by using a pulse width modulation (PWM) technique to input digital signals (0 and 1) into the select line 185 and the data line 170 through the micro component 125 (as a driver component). In some embodiments, the micro component 125 is a trapezoidal shape in the cross-sectional view. In some embodiments, the dielectric layer 175 encapsulates a side surface of the micro component 125. In some embodiments, the internal design of the drive circuits of the micro component 125 may be varied based on different requirements, such as buck circuits with different voltage outputs, protection circuits with anti-electrostatic discharge (ESD), and higher operating efficiencies.

In summary, the embodiments of the present disclosure apply the concept of mass transfer to the semiconductor components. Instead of singulating the semiconductor wafer first (i.e., cutting the semiconductor wafer, including the substrate, into several chips), the semiconductor wafer is processed to form a plurality of the semiconductor components separately on the substrate through the etching process. Then, the separated semiconductor components are transferred to the carrier through the transfer process to obtain the wafer with micro integrated circuit. That is, the micro components may be transferred to the carrier by the laser mass transfer process, which effectively improves the process efficiency and reduces the cost. It will be understood that not all advantages have been necessarily discussed herein, no particular advantage is required for all embodiments, and other embodiments may offer different advantages.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

The foregoing outlines features of several embodiments of the present disclosure so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A wafer with micro integrated circuits, comprising:
a transparent substrate; and
a plurality of micro components, wherein the micro components are each attached to the transparent substrate by a plurality of transparent adhesive layers,
wherein each of the micro components comprises:
a bonding pad in direct contact with the transparent adhesive layer; and
an etching stop layer located on a side of the micro components opposite from the bonding pad.

2. The wafer with micro integrated circuits as claimed in claim 1, wherein the micro components further comprise:
a circuit layer between the etching stop layer and the bonding pad.

3. The wafer with micro integrated circuits as claimed in claim 2, wherein, in a cross-sectional view, the circuit layer is a tapered structure with a long side and a short side opposite to each other, and wherein the short side of the tapered structure corresponds to a side of the circuit layer near the bonding pad, and the long side of the tapered structure corresponds to a side of the circuit layer near the etching stop layer.

4. The wafer with micro integrated circuits as claimed in claim 3, wherein an angle between the long side of the tapered structure and a sidewall of the tapered structure between the long side and the short side is from 45 degrees to 90 degrees.

5. The wafer with micro integrated circuits as claimed in claim 2, wherein the circuit layer comprises at least three sets of driver circuits.

6. The wafer with micro integrated circuits as claimed in claim 2, wherein the circuit layer comprises an active circuit element or a passive circuit element.

7. The wafer with micro integrated circuits as claimed in claim 2, wherein a material of the circuit layer comprises silicon, gallium arsenide, or a combination thereof.

8. The wafer with micro integrated circuits as claimed in claim 1, wherein a thickness of one of the micro components is less than 30 μm.

9. The wafer with micro integrated circuits as claimed in claim 1, wherein a material of the etching stop layer comprises silicon nitride, silicon carbide, or a combination thereof.

10. The wafer with micro integrated circuits as claimed in claim 1, wherein a material of the transparent substrate comprises glass, aluminum oxide, or a sapphire substrate.

11. The wafer with micro integrated circuits as claimed in claim 1, wherein the transparent adhesive layer comprises a laser dissociative material.

12. The wafer with micro integrated circuits as claimed in claim 1, wherein a material of the transparent adhesive layer comprises polyimide (PI), epoxy, silicone, polydimethylsiloxane (PDMS), or polymethylmethacrylate (PMMA).

13. The wafer with micro integrated circuits as claimed in claim 1, wherein a distance between the two adjacent micro components is from 0.5 μm to 100 μm.

14. The wafer with micro integrated circuits as claimed in claim 1, wherein a thickness of the transparent substrate is from 50 μm to 2 mm.

15. The wafer with micro integrated circuits as claimed in claim 1, wherein a material of the bonding pad comprises Al, Cu, Au, TiN, Ti, Pt, Cr, Ni, Pd, or a combination thereof.

16. The wafer with micro integrated circuits as claimed in claim 1, wherein a thickness of the transparent adhesive layers is from 0.5 μm to 50 μm.

17. The wafer with micro integrated circuits as claimed in claim 1, wherein the micro components are transferred to a carrier by laser dissociation of the transparent adhesive layers.

18. The wafer with micro integrated circuits as claimed in claim 17, wherein the micro components are secured to the carrier by an adhesive layer on the carrier.

19. A semiconductor device with micro integrated circuit, comprising:
a carrier with four electrodes;
three light-emitting diodes disposed on the carrier;
a micro component disposed on the carrier, the micro component has a trapezoidal shape in a cross-sectional view; and
a dielectric layer encapsulating a side surface of the micro component;
wherein the micro component has seven electrodes,
wherein four of the seven electrodes are input terminals, and the four of the seven electrodes are electrically connected to the four electrodes respectively, and
wherein the other three of the seven electrodes are output terminals, and the other three of the seven electrodes are electrically connected to the three light-emitting diodes, respectively.
